(19) United States
(12) Patent Application Publication
(10) Pub. No.: US 2014/0197467 A1
(43) Pub. Date: Jul. 17, 2014

(54) HIGH VOLTAGE JUNCTION FIELD EFFECT TRANSISTOR STRUCTURE

(71) Applicant: MACRONIX INTERNATIONAL CO., LTD., Hsin-Chu City (TW)

(72) Inventors: WEI-HSUN HSU, TAIPEI COUNTY (TW); SHUO-LUN TU, HSIN-CHU CITY (TW); SHIH-CHIN LIEN, TAIPEI COUNTY (TW); SHYI-YUAN WU, HSIN-CHU CITY (TW)

(73) Assignee: MACRONIX INTERNATIONAL CO., LTD., HSIN-CHU CITY (TW)

(21) Appl. No.: 13/740,725

(22) Filed: Jan. 14, 2013

(51) Int. Cl. H01L 27/088; H01L 21/76

(52) U.S. Cl. CPC H01L 27/088; H01L 21/76
USPC 257/272; 438/400

(57) ABSTRACT

A JFET structure includes a first JFET having a first terminal and a second JFET neighboring with the first JFET. Both JFETs commonly share the first terminal and the first terminal is between the gate of each JFET. The JFET also provides at least one tuning knob to adjust the pinch-off voltage and a tuning knob to adjust the breakdown voltage of the JFET structure. Moreover, the JFET has a buried layer as another tuning knob to adjust the pinch-off voltage of the JFET structure.

### FIELD OF THE INVENTION

The present invention relates in general to a high voltage JFET (Junction Field Effect Transistor) structure, and more particularly to a tunable JFET structure embedded in a CMOS circuit.

### BACKGROUND

A switch mode power supply (SMPS), which is also known as a switcher, is an electronic power supply that incorporates a switching regulator which converts electrical power efficiently and is usually employed to provide a regulated output voltage. A start-up circuit is usually included in an SMPS and utilized to close power when the converter starts to operate. The requirement of the start-up circuit is to keep the power shut off while providing low leakage.

A high voltage JFET (Junction Field Effect Transistor) is adopted to provide a high pinch-off voltage and low leakage when compared with a traditional format by utilizing a resistor or a depletion MOS as a power control. During operation, since the PN junction of the JFET is reverse biased, the channel between the source and the drain is squeezed in order to be turned off by the increased depletion region. Hence, no carrier can flow in the JFET.

Conventionally, an external JFET is used for a start-up circuit. However, as the size of chip designs becomes more competitive, it would be considered a luxury to reserve a certain area in order to build an external JFET on a limited active region. In addition, with the increasing application of CMOS technology, the process to construct an external JFET may be different from that of the CMOS. Thus, an extra process for allocation is needed in order to build a JFET into a CMOS circuit, which can usually increase cost and time for a manufacturer.

Therefore, it is desirable to provide an embedded JFET for a CMOS device start-up circuit without introducing a different or an extra process. It is also desirable to be able to provide a pinch-off voltage tunable JFET in order to increase the application of the CMOS device.

### SUMMARY OF THE INVENTION

The objective of the present invention is to provide a tunable JFET structure which can be used in a start-up circuit of a CMOS device. The JFET structure has a first tuning knob to adjust the pinch-off voltage of the JFET structure and a second tuning knob to adjust the pinch-off voltage. The second tuning knob is underneath the first tuning knob and close to the substrate.

One embodiment according to the present disclosure includes a JFET structure. The JFET structure includes a first JFET having a first terminal and a second JFET neighboring with the first JFET. Both JFETs commonly share the first terminal, which is between the gate region of each JFET.

Another embodiment is a JFET structure with a plurality of pinch-off channels. The structure includes a substrate of a first conductivity type, and a first JFET which has a first terminal. The structure further includes a second JFET in/on the substrate, wherein the first JFET has a first terminal that is between the first and second JFET and is commonly shared with the second JFET. Moreover, the JFET has a buried layer of a second conductivity type in the substrate and under the first and second JFET.

Another embodiment provides a method of manufacturing a JFET structure. The method includes providing a substrate of a first conductivity type, and also includes forming a first JFET and a second JFET in the substrate, wherein the first and second JFET commonly share a first terminal that is between the gate region of each JFET. Moreover, the method includes forming a buried layer of the second conductivity type under the first and second JFET.

### BRIEF DESCRIPTION OF THE DRAWINGS

The invention will be described according to the appended drawings in which:

FIG. 1 illustrates an effective circuitry of a JFET structure.

FIG. 2 depicts the semiconductor structure of a JFET structure.

FIG. 3 depicts the semiconductor structure of a JFET structure according to one embodiment under reverse bias.

FIG. 4 depicts the semiconductor structure of a JFET structure according to one embodiment.

FIGS. 5 depicts the semiconductor structure of a JFET structure according to one embodiment.

FIGS. 6 depicts the semiconductor structure of a JFET structure according to one embodiment.

FIG. 7 depicts the semiconductor structure of a JFET structure according to one embodiment under reverse bias.

FIGS. 8A and 8B depict the I-V curve comparison of two different embodiments.

FIG. 9 depicts the semiconductor structure of a JFET structure according to one embodiment.

FIG. 10 depicts the semiconductor structure of a JFET structure according to one embodiment.

FIG. 11 is a drawing to illustrate the relationship between the breakdown voltage and the width of the second isolation region of one embodiment.

### DETAILED DESCRIPTION OF THE INVENTION

The embodiments of the present invention are described more fully hereinafter with reference to the accompanying drawings, which form a part hereof, and which show, by way of illustration, specific exemplary embodiments by which the invention may be practiced. This invention may, however, be embodied in many different forms and should not be construed as limited to the embodiments set forth herein; rather, these embodiments are provided so that this disclosure will be thorough and complete, and will fully convey the scope of the invention to those skilled in the art. As used herein, the term “or” or symbol “I” is an inclusive “or” operator, and is equivalent to the term “and/or,” unless the context clearly dictates otherwise. In addition, throughout the specification, the meaning of “a,” “an,” and “the” include plural references. The term “coupled” implies that the elements may be directly connected together or may be coupled through one or more intervening elements.

The following description illustrates embodiments for providing a power closure function of an integrated circuit. Each embodiment possesses a feature configured to have a high pinch-off voltage and a low current leakage.

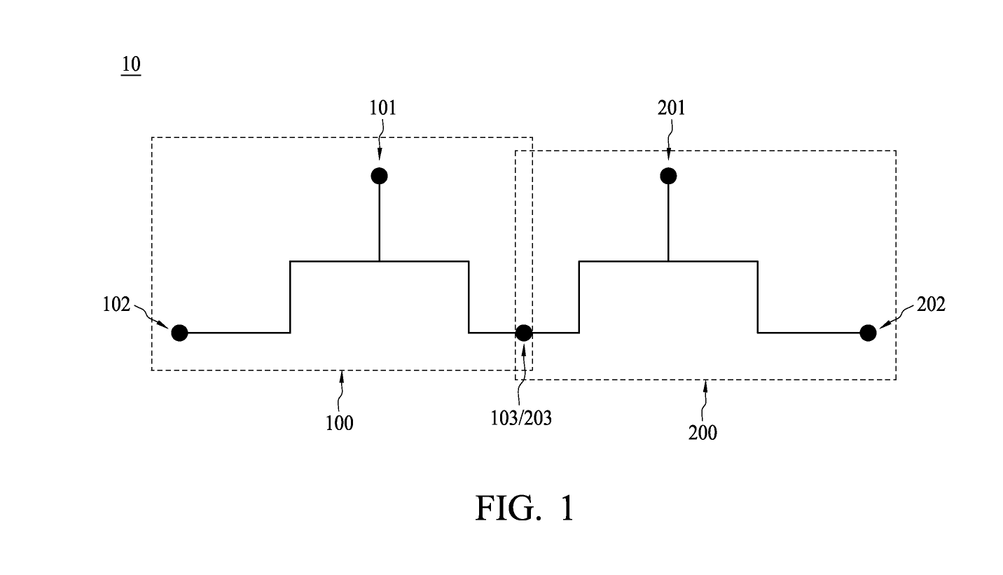

FIG. 1 is a schematic drawing of an embodiment according to the present disclosure. A JFET structure 10 has a first JFET 100 and a second JFET 200. Each JFET has a gate (101 or 201) and at least two terminals (e.g., 102 and 103 for the first JFET). Both JFETs are partially overlapped in order to commonly share a terminal (103 or 203). The JFET 100/200 can be either an n-channel or a p-channel JFET. For an n-channel embodiment, the common terminal 103/203 is the source (a common source configuration). For a p-channel embodiment, the common terminal 103/203 is the drain (a common drain configuration).

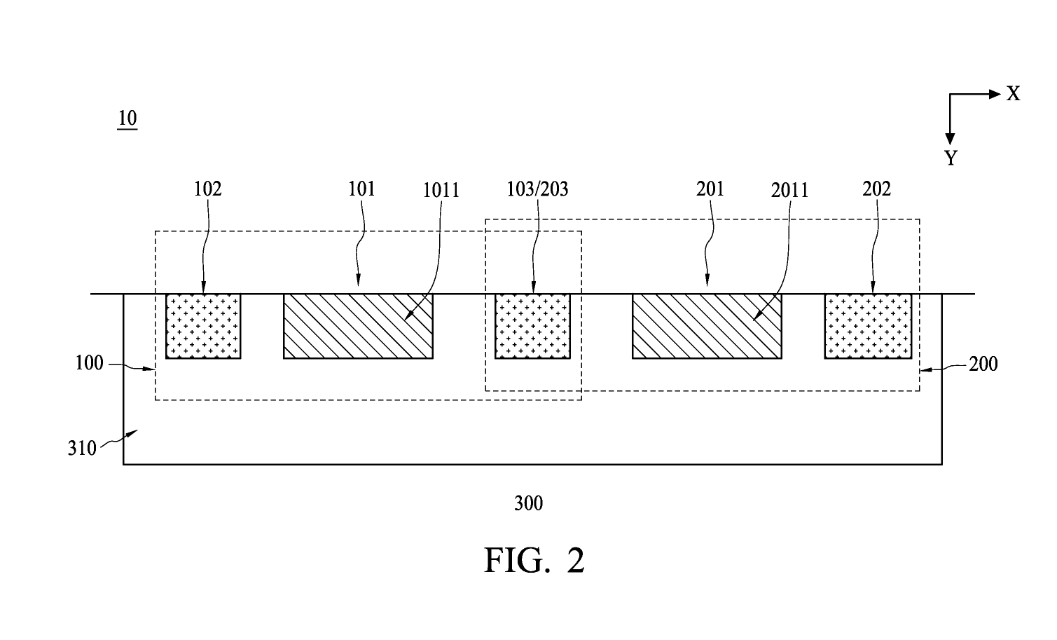

FIG. 2 illustrates the semiconductor structure of the JFET structure 10 as shown in FIG. 1. The construction of each JFET (100 or 200) can be the same as depicted in the present drawing but should not be treated as a restriction in the present disclosure. Firstly, a substrate 300 of a first conductivity type is provided to house the JFET structure 10. It should be noted that the purpose of using “first conductivity type” in contrast with “second conductivity type” in the specification and claims is to differentiate opposite type dopants in each embodiment, which are either n or p-type. Those within this technical field should also appreciate that neither “first conductivity type” nor “second conductivity type” is limited to n or p. For example, if the first conductivity type in an embodiment is n-type (or donor), then the second conductivity type in that embodiment is p-type (or acceptor).

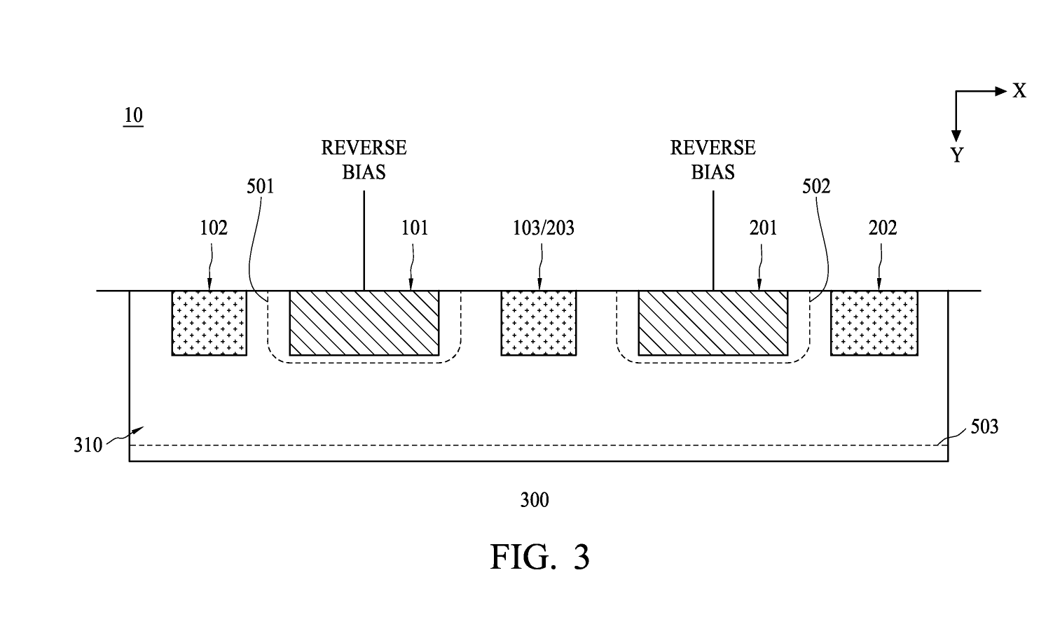

The JFET structure 10 can further have a first well 310 of the second conductivity type formed in the substrate 300. Formation of the first well 310 can be done by ion implantation and/or a diffusion process (e.g., well drive-in). In the present embodiment, the first and second JFET are both n-channel JFETs and lay laterally along the x direction in the first well 310. Accordingly, the commonly shared terminal 103/203 is the source for each JFET, while 102/202 is the drain for the first and second JFET, respectively. The common source 103/203 is disposed between the gate 101 and gate 201 of each JFET. The drain 102/202 can be a doped region of the second conductivity type with a higher concentration than the first well 310. Each gate 101/201 respectively can have a body region 1011/2011 of the first conductivity type. FIG. 3 illustrates a reverse bias applied on gate 101 and 201. The depletion regions 501 and 502 that are between the drains 102/202 and the source 103/203 start expanding. Simultaneously, the depletion region 503 at the interface between the first well 310 and substrate 300 expands as well. If keeping increasing the reverse bias, the depletion regions will keep expanding substantially along the x direction, or y direction, or composition of x and y. The expanded depletion regions restrict the current (or electronic current) channel and finally pinch off the channel between the source 103/203 to the drains 102/202.

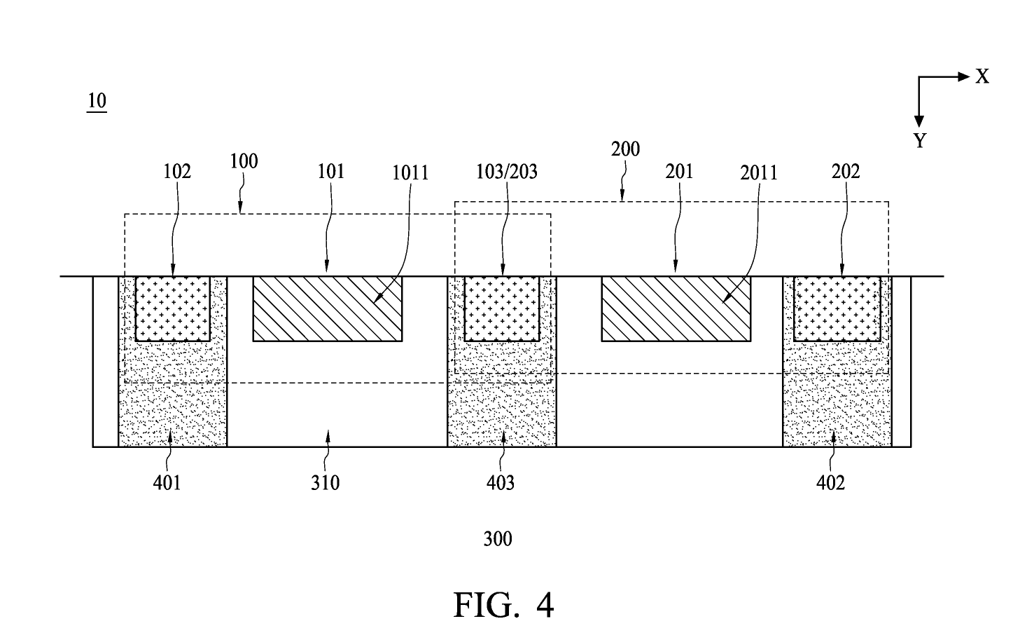

In some particular embodiments as illustrated in FIG. 4, second wells 401-403 can be formed to surround the common source 103/203 or the drains 102/202. The conductive type of the second wells are the same with the surrounded terminals. The resistance at each terminal can be reduced by adding the second wells. It is not necessary to have a respective second well for each terminal. Various combinations can be elected by the designer as required.

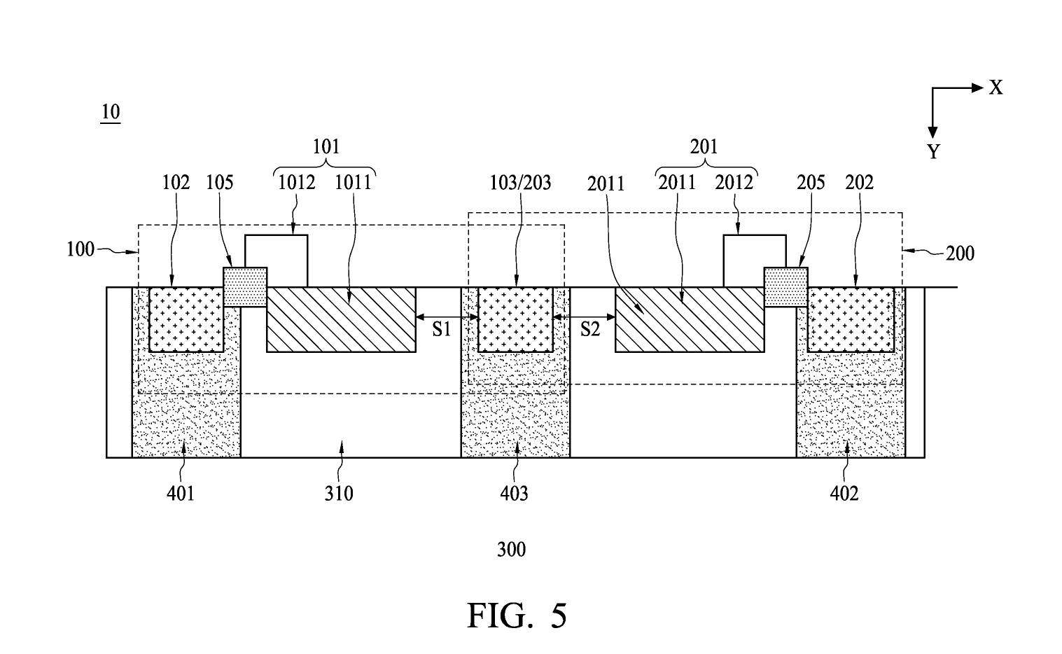

FIG. 5 illustrates another embodiment of the present invention. The commonly shared terminal 103/203 is separated from the gate 101/201 and the body region 1011/2011. In the present embodiment, the commonly shared terminal 103/203 is surrounded by the first well 310 with a distance S1 to the first body region 1011 and a distance S2 to the second body region 2011, respectively. The distance S1 or S2 is configured as a tuning knob, which can create an adjustable pinch-off voltage for the JFET. As the value of S1 or S2 is increased, the pinch-off voltage for the JFET structure 10 is also increased.

The value of S1 and S2 can be controlled by only modifying the mask for patterning the terminal 102, 103, 202, and 203. It is not necessary to create another photo layer in order to create the tuning knob. In one embodiment, S1 is designed to be equal to S2. With the aid of the tuning knob, the feasibility to tune the pinch off voltage by adjusting S1 or S2 provides a larger design window. A first isolation region (not shown here) can be inserted in the space between the common terminal 103/203 and the body region 1011/2011 as well. Referring to FIG. 5 and using the first JFET 100 as an example, the first JFET 100 includes a gate 101 which is composed of a gate layer 1012 on a first well 310 and a body region 1011 in the first well 310. The first well 310 is of a first conductivity type and the body region 1011 is doped with a second conductivity type. The body region 1011 is coupled to the gate layer 1012. The JFET 100 also has a first terminal 103 and a second terminal 102 of the first conductivity type in the first well 310. A second isolation region 105 is between the second terminal 102 and the gate 101. Similar structure can be also arranged for the second JFET 200. The gate 201 includes a gate layer 2012 on a first well 310 and a body region 2011 in the first well 310. The first well 310 is of a first conductivity type and the body region 2011 is doped with a second conductivity type. The body region 2011 is coupled to the gate layer 2012. A second isolation region 205 is between the terminal 202 and the gate 201.

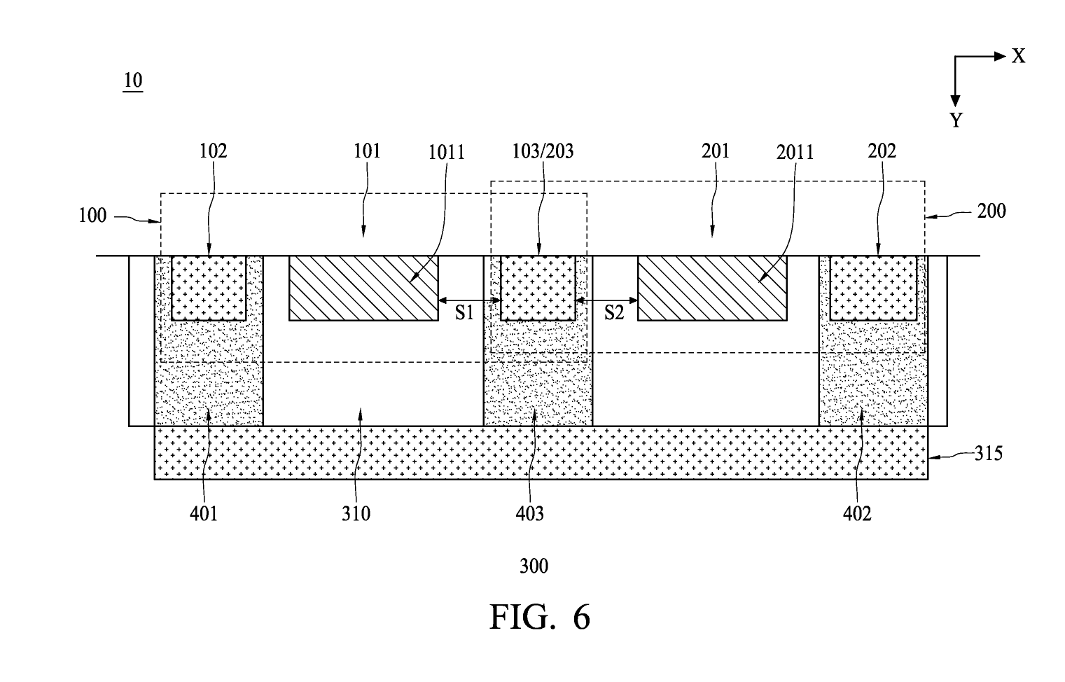

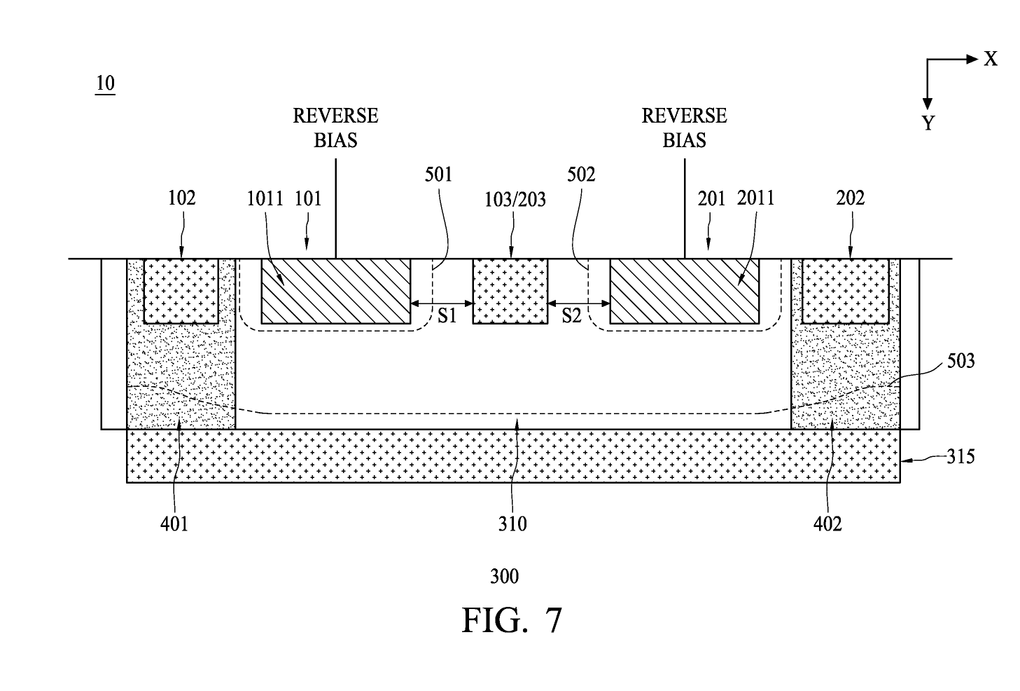

FIG. 6 illustrates another embodiment of the present invention. The JFET structure 10 as depicted in FIG. 4 further includes a doped buried layer 315. Opposite to the body region 1011/2011, the buried layer 315 is doped with the second conductivity type, which is n-type in the present embodiment. The buried layer 315 is arranged underneath the first well 310 and preferably under the first JFET 100 and second JFET 200 with a predetermined distance. The dopant concentration of the buried layer 315 is preferably to be greater than the first well 310. Second wells 401-403 can be formed to surround the common source 103/203 or the drains 102/202. The conductive type of the second wells are the same with the surrounded terminals. The resistance at each terminal can be reduced with the second wells. It is not necessary to have a respective second well for each terminal. Various combinations can be elected by the designer as required. In some embodiments, there are only second wells 401 and 402 formed surrounding the drains 102 and 202. FIG. 7 illustrates a reverse bias applied on gate 101 and 201. The depletion regions 501 and 502 that are between the drains 102/202 and the source 103/203 start expanding. Simultaneously, the depletion region 503 at the interface between the buried layer 315 and the substrate 300 expands as well. If keeping increasing the reverse bias, the depletion regions will keep expanding substantially along the x direction, or y direction, or composition of x and y. The expanded depletion regions restrict the current (or electronic current) channel and finally pinch off the channel between the source 103/203 to the drains 102/202. In some embodiments, the dopant concentration of the buried layer is configured to be greater than the first well 310, the size of the depletion region 503 is greater than those without the buried layer 315, hence the pinch off voltage can be increased by adding the buried layer 315.

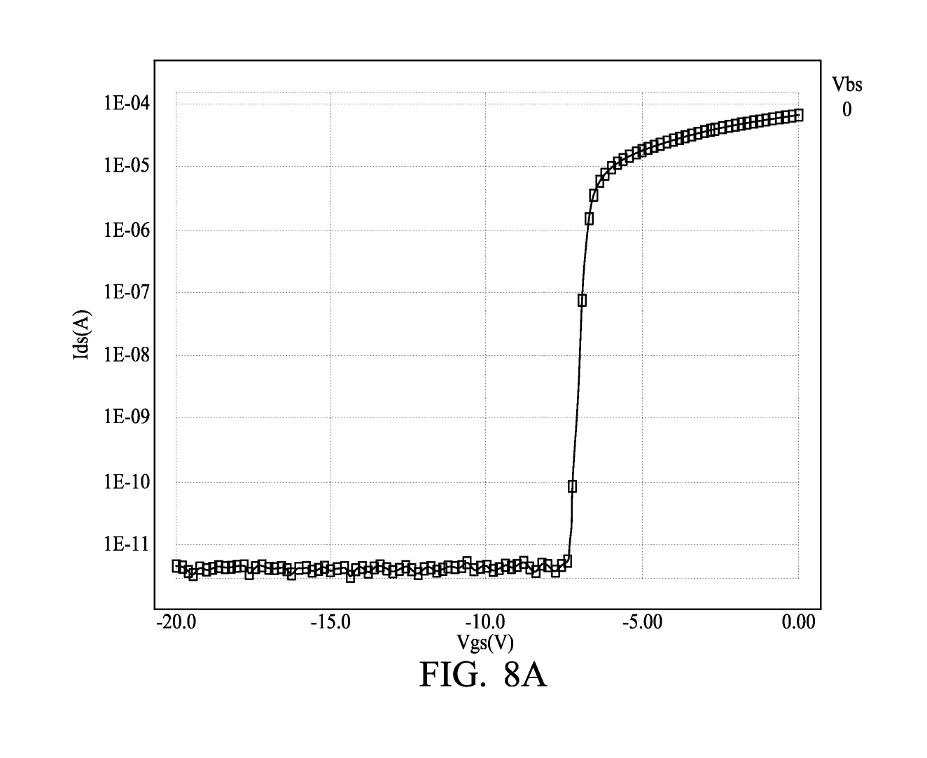

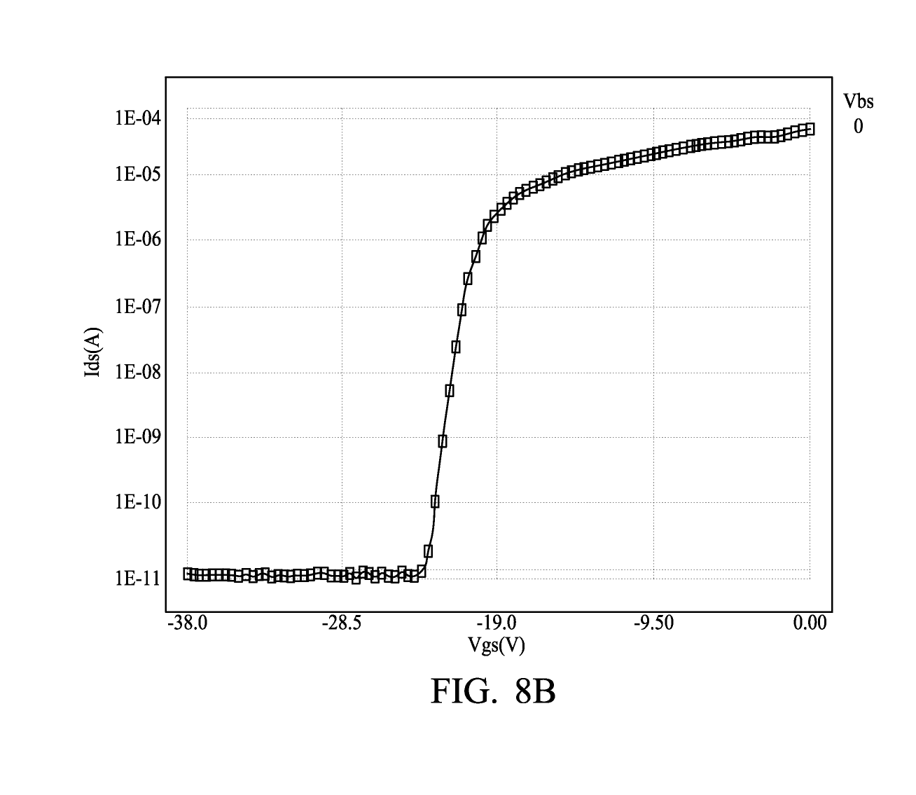

FIG. 8A is an I-V (current versus gate voltage) curve of one embodiment including two JFETs with a common source. Without the buried layer 315, the pinch-off voltage is about −7V. FIG. 8B is an I-V curve of an embodiment similar to FIG. 8A except that 5B further has a buried layer 315 under the JFETs. Apparently, FIG. 5B has a larger pinch-off voltage, which is −23V as compared to −7V in FIG. 5A.

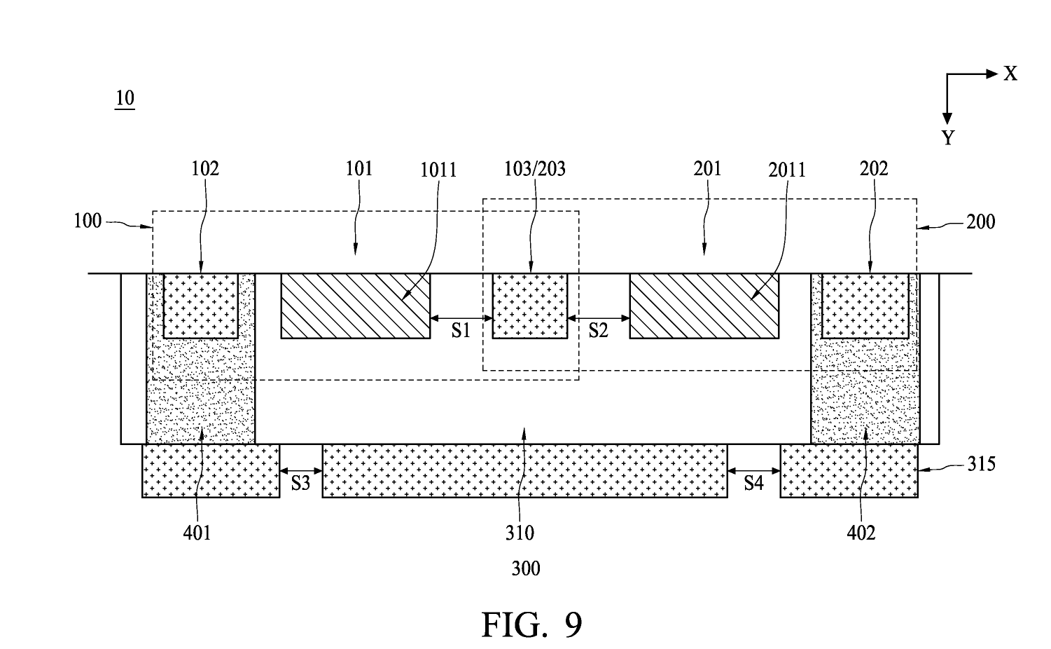

The buried layer 315 can also be segmented into a plurality of sections as shown in FIG. 9. There are at least two spaces between the sections. In the present embodiment, there are three different sections and two spaces in between. One space is S3 and the other one is S4. The purpose of dividing the buried layer 315 into segments is to provide a knob that can adjust the pinch-off voltage. By increasing either S3 or S4, the pinch-off voltage of the JFET structure 10 can be reduced compared to a non-divided buried layer 315. For example, in one embodiment with a buried layer without segmentation, the pinch-off voltage can be designed to approximately −27V. By dividing the buried layer 315 into different sections, the pinch-off voltage can be lowered to a desired value. The buried layer 315 is formed at a predetermined depth under the JFETs by an ion-implantation process with a mask on the substrate. To segment the buried layer 315, it is only necessary to modify the same mask to block the ions penetrating into the space region without creating an extra mask or process step. In one embodiment, S3 can be designed to be equal to S4. In another embodiment, the buried layer 315 is segmented into a plurality of sections with equal space.

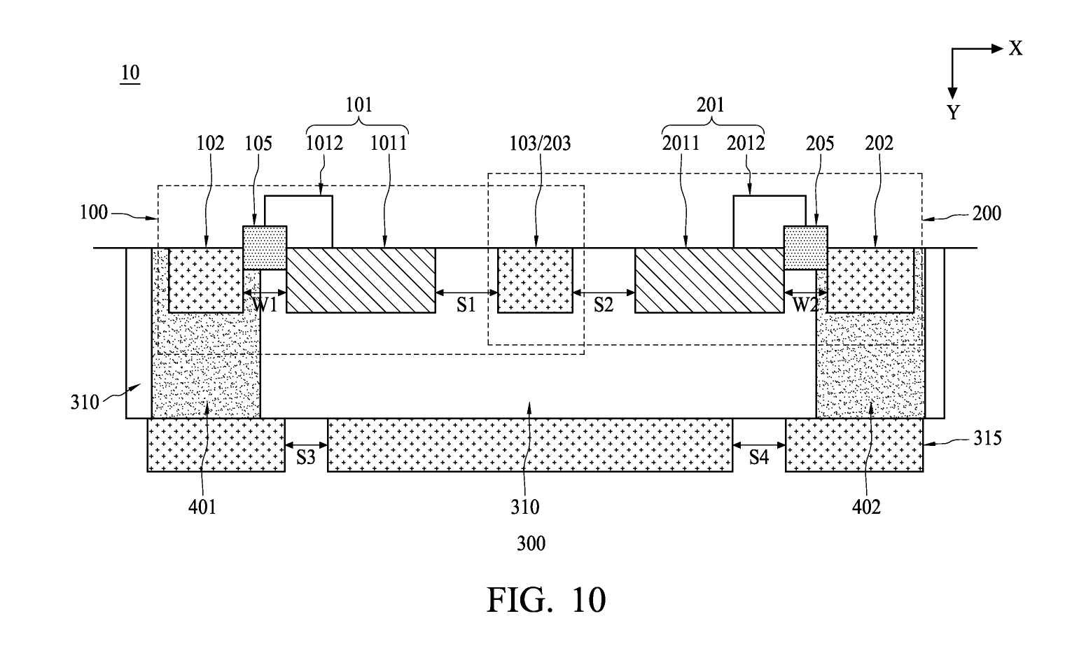

FIG. 10 illustrates a JFET structure 10 according to the present disclosure. The JFET structure has a first JFET 100 and a second JFET 200. The structure of each JFET can be similar as shown in FIG. 10, wherein the first JFET 100 is an example to be used for the following description. The first JFET 100 includes a gate 101 and the gate has a body region 1011 in the first well 310. The first well 310 is of a first conductivity type and the body region 1011 is doped with a second conductivity type. The JFET 100 also has a first terminal 103 and a second doped region 102 of the first conductivity type in the first well 310. The first terminal 103 can be a doped region of the same conductivity of the second doped region 102, wherein the second doped region 102 is another terminal (cathode or anode) for the JFET 100. If the first terminal 103 is the cathode, then the second doped region 102 is the anode and vice versa. The first terminal 103 (or 203) is commonly shared by the first JFET 100 and the second JFET 200; thus the first JFET 100 and the second JFET 200, together, form either a common source or common drain JFET structure.

A space S1 or S2 is formed between the first terminal 101 and the gate(101 or 201) and configured as a tuning knob to adjust the pinch-off voltage when the gate layer 101 is reverse biased. The space can optionally include a first isolation region (not shown) between the body region 1011 and the first terminal 103. And the first isolation region can be a field oxide, shallow trench isolation (STI), deep trench isolation (DTI) or SOI substrate.

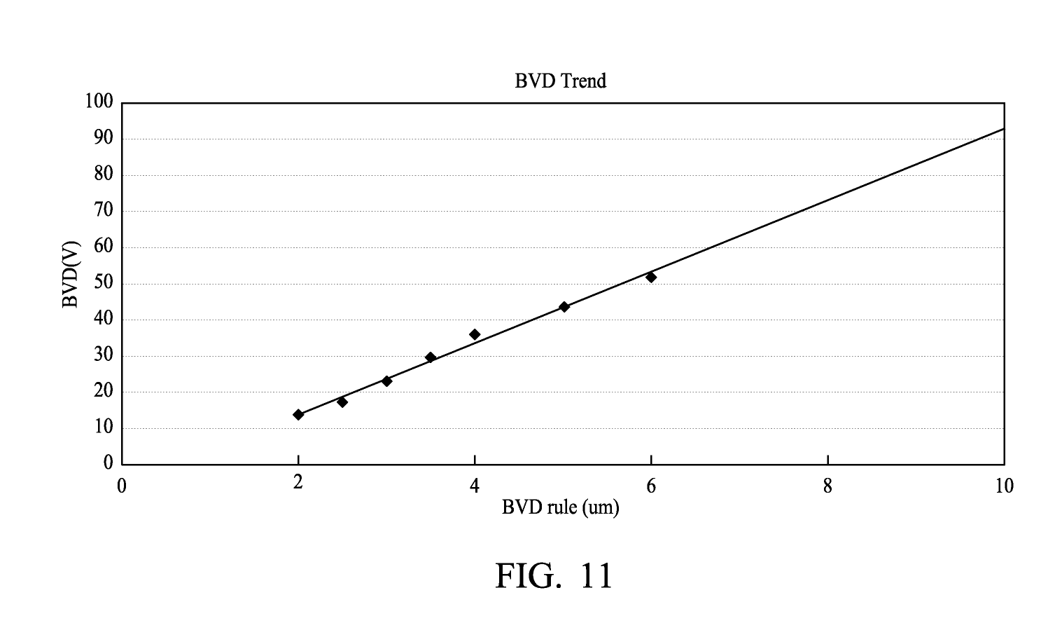

Additionally, the JFET 100 can also have a second isolation region 105 between the second doped region 102 and the gate 101. The second isolation region 105 can be a field oxide, shallow trench isolation (STI), deep trench isolation (DTI) or SOI substrate. In one embodiment as shown in FIG. 10, the gate layer 101 lays on a portion of the second isolation region 105. The second isolation region 105 is configured as a tuning knob for adjusting the breakdown voltage of the JFET. When the width of the isolation region 105 is increased, the breakdown voltage is increased. FIG. 11 depicts an embodiment according to the present disclosure showing how breakdown voltage (BVD value) is changed along with the width (x-axis) of the second isolation region 105.

Referring back to FIG. 10, those skilled in the art should appreciate that the purpose of the present invention is to provide at least one tuning knob for the pinch-off voltage by arranging two JFETs sharing a common terminal 103/203, in which the common terminal 103/203 is either a source or a drain. Each JFET can be a standard MOS structure such as LDMOS, EDMOS, or BCDMOS structure, and manufactured by only adding or modifying a few masks while making a CMOS circuit, simultaneously. With the common terminal configuration, the pinch-off voltage can be adjusted by changing the space between the common terminal and the gate 101/201. Another pinch-off voltage tuning knob can be created by adding a dividable buried layer 315 under the first well 310 to adjust the pinch off voltage of the JFET structure 10.

Another feature of the present disclosure is to have a tuning knob for the breakdown voltage of the JFET structure 10, as shown in FIG. 10 with a field plate design (the gate layer 1012 partially covers the second isolation region 105). The breakdown voltage of the JFET can be pre-determined by adjusting the width w1 of the second isolation region 105, or the width w2 of the second isolation region 205.

According to the embodiments as described above, the JFET structure in the present invention can be widely adopted in circuit designs. More particularly, the adjustable pinch-off and breakdown features provide those skilled in the art a larger design window without additional costs and design restrictions.

The methods and features of this invention have been sufficiently described in the above examples and descriptions. It should be understood that any modifications or changes without departing from the spirit of the invention are intended to be covered in the protection scope of the invention.

What is claimed is:

1. A JFET structure, comprising:
a first JFET having a first terminal; and
a second JFET neighboring with the first JFET and commonly sharing the first terminal with the first JFET, wherein the first terminal is between the gate of each JFET.

2. The JFET structure in claim 1, wherein the commonly shared first terminal is a source or a drain of the JFETs.

3. The JFET structure in claim 1, wherein the first terminal is equally spaced from the gate of each JFET.

4. The JFET structure in claim 4, further comprising a first isolation region between the first terminal and the gate

5. The JFET structure in claim 1, further comprising a well with a first conductivity type, wherein the well is configured to accommodate the first and the second JFET.

6. The JFET structure in claim 5, wherein the gate comprises:
a gate layer on the well; and
a first doped region of a second conductivity type in the well, wherein the first doped region is coupled with the gate layer.

7. The JFET structure in claim 6, further comprising a second doped region of the first conductivity type in the well and a second isolation region, wherein the second doped region is separated from the gate by the second isolation region.

8. The JFET structure in claim 6, wherein the common terminal is a doped region with the first conductivity type.

9. A JFET structure providing a plurality of pinch-off channels, wherein the JFET structure comprises:
a substrate of a first conductivity type;
a first JFET having a first terminal;
a second JFET in/on the substrate, wherein the first terminal is commonly shared with the second JFET, in which the first terminal is between the first and second JFET; and
a buried layer of a second conductivity type in the substrate, wherein the buried layer is under the first and second JFET.

10. The JFET in claim 9, wherein the buried layer is segmented into a plurality of sections.

11. The JFET in claim 9, wherein each section is separated by an equal space.

12. The JFET structure in claim 9, wherein the commonly shared first terminal is a source or a drain of the JFETs.

13. The JFET structure in claim 9, wherein the first terminal is equally spaced from the gateof each JFET.

14. The JFET structure in claim 13, further comprising a first isolation region between the first terminal and the gate.

15. The JFET structure in claim 9, further comprising a well with a second conductivity type in the substrate, wherein the well is configured to accommodate the first and the second JFET.

16. The JFET structure in claim 15, wherein the gate comprises:
a gate layer on the well; and
a body region of a first conductivity type in the well and coupled with the gate layer.

17. The JFET structure in claim 16, further comprising a second doped region of the second conductivity type in the well and a second isolation region, wherein the second doped region is separated from the gate by the second isolation region.

18. A method of manufacturing a JFET structure, wherein the method comprises:
providing a substrate of a first conductivity type;
forming a first JFET and a second JFET in the substrate, wherein the first and second JFET commonly share a first terminal, in which the first terminal is between the gate of each JFET; and
forming a buried layer of the second conductivity type under the first and second JFET.

19. The method of claim 18, further providing a plurality of spaces between the first terminal and the corresponding gate, wherein each space is equal.

20. The method of claim 18, further segmenting the buried layer into a plurality of sections.

21. The method of claim 20, further forming an equal space between each section.

22. The method of claim 18, further forming an isolation region between a second terminal and a gate of each JFET.

23. The method of claim 18, further forming a second isolation region between the gate and the first terminal.
